(19) United States
(12) Patent Application Publication
(10) Pub. No.: US 2025/0271755 A1
(43) Pub. Date: Aug. 28, 2025

(54) CONTROLLED ENVIRONMENT PROCESSING, REST STEPS, AND BAKING PROCESSES FOR METAL OXIDE-BASED RESIST PATTERNING

(71) Applicant: Inpria Corporation, Corvallis, OR (US)

(72) Inventors: Peter De Schepper, Wijnegem (BE); Sonia Castellanos Ortega, Leuven (BE); Jan Doise, Leuven (BE)

(21) Appl. No.: 19/065,726

(22) Filed: Feb. 27, 2025

Related U.S. Application Data
(60) Provisional application No. 63/558,729, filed on Feb. 28, 2024.

(51) Int. Cl. G03F 7/004; G03F 7/16; G03F 7/20

(52) U.S. Cl. CPC G03F 7/0043; G03F 7/168; G03F 7/2004

(57) ABSTRACT

Methods provide for advantageous processing of substrates with metal oxide-based resists between irradiation and development for forming a physical pattern. One or more post irradiation heating steps can be conducted around rest steps under a controlled environment. Process steps can involve ambient environments contacting the irradiated film that can be at low pressures, such as no more than 150 Torr or under high relative humidity, such as at least about 65%. This processing can be effective to reduce dose-to-size performance to basically reduce irradiation dose to achieve target patterning.

### CROSS REFERENCE TO RELATED APPLICATIONS

This application claims priority to copending U.S. provisional patent application 63/558,729 to De Schepper et al., “Controlled Environment Processing and Baking Processes for Metal Oxide Resist,” incorporated herein by reference.

### FIELD OF THE INVENTION

The invention relates to post irradiation process for EUV photolithography to improve the patterning performance through manipulations in the process flow. Process flows generally include one or more rest steps following irradiation, which can be interspersed around one or more post-exposure bake (PEB) steps. The atmosphere composition as well as the pressure during the heating steps as well as during the rest steps can be selected to achieve desired processing results. Steps involving low pressure or high moisture can be selected to drive certain processes within the irradiated films.

### BACKGROUND OF THE INVENTION

Semiconductor fabrication generally consists of iterative processing steps comprising deposition, etching, photopatterning, and the like. Photopatterning is generally performed through the process of lithography wherein a photosensitive material (i.e., a photoresist) is irradiated with an appropriate radiation source, such as ultraviolet (UV), extreme ultraviolet (EUV), or an ion beam, to induce solubility changes in the irradiated material relative to the non-irradiated material. Improvements in this photolithographic process are generally desired to reduce costs of device fabrication and to improve pattern fidelity and device performance, among others.

In the effort to continue to reduce device sizes produced from photolithography, photolithographic systems have been developed to use EUV which has very short wavelengths that can allow very small image formation and high-resolution patterns. Organometallic and metal oxide coatings have been shown to be useful as suitable photoresist materials for achieving high-resolution patterning and are very promising for commercial use for patterning with EUV lithography, as well as for electron beam patterning. To further increase the performance of metal oxide resists, it is desirable for materials and processing to enable lower doses (i.e., higher sensitivity) for patterning. Additionally, it is desirable to improve the process window (e.g., resolution of a wider range of pattern sizes without defects) of metal oxide resist materials.

### SUMMARY OF THE INVENTION

In a first aspect, the invention pertains to a method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature from about 45° C. to about 220° C. for about 0.1 minutes to about 30 minutes;
after removing the irradiated structure from the first temperature, resting the irradiated structure for about 1 minute to about 5000 minutes to form a rested structure;
heating the rested structure at a second temperature from about 45° C. to about 250° C. for about 0.1 minutes to about 30 minutes; and
developing the coated substrate after the second heating step to form a physically patterned structure.

In a further aspect, the invention pertains to a method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature from about 45° C. to about 220° C. for about 0.1 minutes to about 30 minutes;
after removing the irradiated structure from the first temperature, resting the irradiated structure for about 1 minute to about 5000 minutes at a pressure of at least about 600 Torr to form a first rested structure;
resting the first rested structure at a pressure of no more than about 150 Torr for 0.1 minutes to about 30 minutes to form a second rested structure;
resting the second rested structure for about 1 minute to about 5000 minutes at a pressure of at least about 600 Torr to form a third rested structure;
heating the third rested structure at a second temperature from about 45° C. to about 250° C. for about 0.1 minutes to about 30 minutes; and
developing the coated substrate after the second heating step to form a physically patterned structure.

In another aspect, the invention pertains to a method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature from about 45° C. to about 220° C. for about 0.1 minutes to about 30 minutes to form a first heated structure;
resting the first heated structure at a relative humidity of at least about 65% for 0.1 minute to about 5000 minutes to form a rested structure;
heating the rested structure at a second temperature from about 45° C. to about 250° C. for about 0.1 minutes to about 30 minutes; and
developing the coated substrate after the second heating step to form a physically patterned structure.

In other aspects, the invention pertains to a method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature under an elevated relative humidity corresponding to a room temperature relative humidity of at least about 61% from about 45° C. to about 220° C. for about 0.1 minutes to about 30 minutes;
resting the irradiated structure for about 1 minute to about 5000 minutes to form a rested structure;
heating the rested structure at a second temperature from about 45° C. to about 250° C. for about 0.1 minutes to about 30 minutes; and
developing the coated substrate after the second heating step to form a physically patterned structure.

In additional aspects, the invention pertains to a method for patterning a coated substrate with radiation wherein the coated substrate has a substrate with a film on a surface of the substrate and wherein the film comprises an organotin composition, the method comprising:
irradiating a coated substrate with radiation to form an irradiated structure;
resting the irradiated structure for a first rest period for about 1 minute to about 30 minutes to form a first rested structure;
heating the rested structure at a first temperature from about 45° C. to about 220° C. under an elevated relative humidity corresponding to a room temperature relative humidity of at least about 61% for about 0.1 minutes to about 30 minutes;
after removing the irradiated structure from the first temperature, resting the irradiated structure for a second rest period from about 0.1 minutes to about 5000 minutes to form a further rested structure wherein at least a portion of the second rest period comprises contacting the irradiated coated substrate with an inert atmosphere, a pressure of no more than about 150 Torr, or a relative humidity of at least about 65%; and
developing the stored structure to form a physically patterned structure.

### BRIEF DESCRIPTION OF THE DRAWINGS

FIG. 1 shows an overall process flow for lithography process using metal oxide-based (organometallic) resist with optional rest steps shown between each step.

FIG. 2A is a schematic of cross-sectional views of an irradiated metal oxide-based photoresist structure showing smaller-than-desired feature sizes after a short post-exposure bake (PEB).

FIG. 2B is a schematic of cross-sectional views of an irradiated metal oxide-based photoresist structure showing T-topping of features after a long PEB.

FIG. 2C is a schematic of cross-section views of an irradiated metal oxide-based photoresist structure showing enhanced profiles of features after performing a rest step between two separate PEBs.

FIG. 3 shows a process flow for patterning a metal oxide-based photoresist with optional rest steps R1 through R5 between each step.

FIG. 4 shows SEM images for photoresists processed with and without a rest step between PEBs.

FIG. 5 shows a plot of smallest CD imageable (cliff lower (nm)) versus dose-to-size (mJ/cm²) for photoresists processed with and without a rest step between PEBs.

FIG. 6 shows the process flows for patterning a set of organotin photoresists with and without vacuum rest steps between the two PEB steps.

FIG. 7 shows SEM images for organotin photoresists processed with a first PEB in air, a rest step, and a second PEB in air, with the rest step having been performed in air (left image) or air/vacuum/air (right image).

FIG. 8 shows SEM images for photoresists processed with a first PEB in air, a rest step, and a second PEB in nitrogen, with the rest step having been performed in air (left image) or air/vacuum/air (right image).

### DETAILED DESCRIPTION OF THE INVENTION

Improvements in patterning performance of metal oxide based (organometallic) photoresists can be improved by tailoring the post irradiation processing leading to development. The processing adjustment can involve control of the ambient environment seen by metal oxide resist films and/or by performance of multiple post-exposure bake (PEB) steps as described herein. The ambient environment can involve controlling the atmosphere during a PEB step and/or controlling the atmosphere during resting and/or wafer transfer. During the PEB process, densification and oxide-hydroxide network formation is promoted through the condensation of radiolysed metal species and potentially cleaved organic species. It has been discovered that performing multiple post exposure bakes can allow for a reduction in dose necessary to achieve a desired critical dimension (CD). Similarly, control of the ambient environments during the processing and in-between process steps (e.g., during storage and/or transport) may improve processing reproducibility. Controlling the environment during a delay period, storage and/or transport, can improve control over the post irradiation process progression. Control of the moisture levels during either a bake step and/or a delay step can further provide additional control over the progress of material condensation and contrast establishment between irradiation and image development. Contrary to previous understanding, delay steps under low pressure environments are found to improve patterning. The goal is to adjust the predevelopment processing to improve the post development patterning results for a particular irradiated pattern.

In a general EUV lithography process using Applicant's metal oxide (organometallic) resist, a single PEB is generally performed at elevated temperature after exposure to EUV radiation in order to drive hydrolysis/condensation reactions within the irradiated regions of the material. Hydrolysis/condensation reactions within the irradiated regions generally results in a higher density and/or lower solubility irradiated material and can thereby increase the contrast between the irradiated and non-irradiated material. The PEB is generally performed in ambient atmosphere in the presence of water and/or other O-containing species which can drive the hydrolysis/condensation of radiolysed species within the resist to form a metal oxide hydroxide network. As the PEB duration and/or temperature increases, further polymerization of the oxide hydroxide network can occur and can result in a reduction the dose-to-size (DtS) of target patterned features. However, the rate of hydrolysis/condensation generally increases with temperature which leads to a reduction in the distance water and/or other O-containing species can diffuse without reacting. As a result, the resist profile can be negatively affected due to incomplete hydrolysis/condensation reactions near the bottom of the film which can lead to poor pattern integrity and smaller process windows.

Applicant's previous work has established that the release of organic components from irradiated resist film can take place upon irradiation (radiolysis) and furthermore as a result of a PEB step wherein a radiation induced thermolysis process occurs. Thus, while irradiation can directly free some organics, other species seem to be formed that are not released from the material until the post exposure heating step. The mechanism of thermal release is not known, and any intermediate species are similarly not known. The organic content can be measured using IR spectra. See, for example, published U.S. patent application 2024/0085785 to Kasahara et al., entitled “Additives for Metal Oxide Photoresists, Positive Tone Development With Additives, and Double Bake Double Development Processing,” incorporated herein by reference. The processing described herein provides the ability to further improve the contrast enhancement from the thermal processing.

An invention described herein comprises multiple PEB steps separated by lower temperature rest periods and controlled ambient environments to enable and control for water molecules to diffuse into the resist film. At lower temperatures, such as during storage and/or resting between PEBs, the temperature is believed to be generally too low for significant condensation to occur since solid state reorganization can involve significant atomic motion enhanced at higher temperatures, and thus the hydration of metal oxide resist film can be enhanced due to casier diffusion through the less condensed material. Accordingly, it can be desirable to expose the irradiated resist to a high humidity environment prior to heating the resist in a PEB to promote hydration of the metal oxide resist film without inducing significant condensation/densification from heating. By performing a multi-step process comprising multiple PEB steps and rest steps, a more uniform resist profile can be achieved by enabling more water and/or other O-containing species to reach the bottom of the irradiated resist without significantly reacting and can therefore drive hydrolysis/condensation reactions in a subsequent PEB. This processing with multi-bake steps separated by rest steps and/or multiple rest steps separated by bake steps can allow for a reduction in EUV dose necessary to achieve a desired critical dimension (CD), while also improving the resist profile and therefore reducing pattern collapse defects.

After exposure to EUV radiation, water and/or other O-containing species can diffuse into the irradiated resist material to drive hydrolysis/condensation reactions and can result in the formation of an insoluble metal oxide hydroxide network. These reactions can occur particularly rapidly during heating, such as during a PEB process. After performing a first PEB process, the resist can be rested without heating to enable further absorption/diffusion of water and/or other O-containing species into the resist film without significantly driving hydrolysis/condensation reactions. A subsequent PEB can then be performed to drive substantial hydrolysis/condensation reactions in the irradiated resist material driven by the presence of water and/or other O-containing species.

Metal oxide photoresists, and in particular organotin photoresists, have been broadly described in U.S. Pat. No. 9,310,684B2 (herein the '684 patent) to Meyers et al., entitled “Organometallic Solution Based High Resolution Patterning Compositions,” U.S. Patent Publication U.S. Pat. No. 10,642,153B2 (herein the '153 patent) to Meyers et al., entitled “Organometallic Solution Based High Resolution Patterning Compositions and Corresponding Methods,” and U.S. Patent Publication U.S. Pat. No. 10,228,618B2 (herein the '618 patent) entitled “Organotin Oxide Hydroxide Patterning Compositions, Precursors, and Patterning”, all of which are incorporated herein by reference. In general, these organotin photoresist materials are deposited as coatings in which Sn atoms are associated in an oxo-hydroxo network through Sn—OH and Sn—O—Sn bonds along with intact Sn—C bonds. The intact Sn—C bonds prevent extended dense network formation, and thus can maintain suitable solubility of the film in a developer. Exposure of organotin coatings to appropriate radiation sources, such as extreme ultraviolet (EUV), ultraviolet (UV), electron beams, and the like, results in cleavage of the Sn—C bond and allows for further densification and/or condensation of the exposed area, thereby increasing the solubility contrast between exposed, which are generally carbon-deficient, and unexposed regions, which are generally carbon-rich relative to the exposed regions. In this way, patterning of the coating can be realized after development. Applicant has developed synthesis techniques allowing for the effective production of precursors with a wide range of R group structures, which can contain unsaturated bonds, aromatic groups, heteroatoms and various combinations thereof. See, for example, published U.S. patent application 2024/0199658 to Jilek et al. (hereinafter the '658 application), entitled “Direct Synthesis of Organotin Alkoxides,” U.S. Pat. No. 10,787,466 to Edson et al., entitled “Monoalkyl tin compounds with low polyalkyl contamination, their compositions and methods”, and published U.S. patent application 2022/00064192 to Edson et al., entitled “Methods to Produce Organotin Compositions With Convenient Ligand Providing Reactants,”, all of which are incorporated herein by reference.

The photoresist films can generally be formed from the organotin compositions described in the '684, '153, and '618 patents referenced above. The organotin photoresist films can be deposited by appropriate solution-based methods, such as spin coating, and/or by appropriate vapor-based methods, such as chemical vapor deposition (CVD), atomic layer deposition (ALD), physical vapor deposition (PVD), and the like.

In some embodiments, the organotin photoresist can be deposited using spin-coating methods, such as those described in the '684 patent. In such spin-coating methods, an organotin photoresist solution comprising organotin precursors is used to form an organotin photoresist film that generally can be described by an organotin oxide hydroxide composition. The organotin precursors are generally hydrolytically sensitive compositions described by the formula RSnL₃ and/or its hydrolysates, wherein R is a linear, branched, cyclic, or aromatic hydrocarbyl ligand and L is a hydrolysable ligand, that participate in rapid hydrolysis and condensation reactions upon deposition. Some suitable organotin photoresist solutions are generally described in U.S. Pat. No. 11,300,876, entitled “Stable Solutions of Monoalkyl Tin Alkoxides And Their Hydrolysis and Condensation Products” by Jiang et. al, and in U.S. Pat. No. 11,498,934 entitled “Monoalkyl Tin Trialkoxides and/or Monoalkyl Tin Triamides With Low Particulate Contamination and Corresponding Methods” by Clark et. al., both of which are incorporated herein by reference.

In some embodiments, the organotin photoresist film can be deposited using vapor-based methods, such as those described in U.S. Pat. No. 10,732,505 entitled “Organotin Oxide Hydroxide Patterning Compositions, Precursors, and Patterning” by Meyers et. al, incorporated herein by reference. Vapor-based deposition methods can generally comprise reacting an organotin precursor vapor with an oxygen-containing vapor, such as H₂O, O₂, O₃, H₂O₂, R′OH, to form an organotin photoresist film comprising organotin oxide hydroxide. To facilitate deposition of the organotin photoresist film, the substrate can be heated or cooled during the vapor-deposition process. In general, the pressures and temperatures within the vapor-deposition process chamber can be selected to control the process.

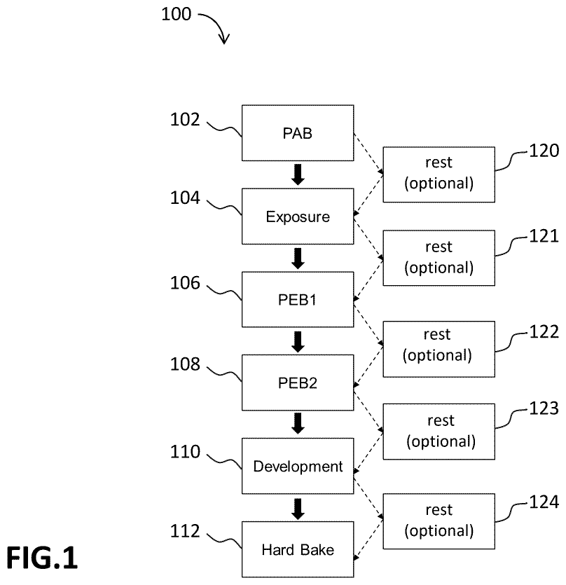

Referring to FIG. 1, the general process flow (100) generally comprises depositing the film; performing a post application bake (PAB) 102; irradiating the film 104; a post irradiation processing, which can comprise a post exposure bake (PEB) 106 and an optional second post-exposure bake 108; development 110; and post development processing, such as a hard bake 112, in which various optional rest or delay steps (120-124) are possible along the process flow. Applicant has previously examined the effects of delay steps between PAB and irradiation and between irradiation and PEB. See U.S. Pat. No. 11,947,262 to Telecky et al. (hereinafter the '262 patent), entitle “Process Environment for Inorganic Resist patterning,” incorporated herein by reference. As found in the '262 patent, the delay between the PAB and the irradiation had little effect, but the delay between irradiation and the PEB had a significant effect on the critical dimension.

The present processing approaches find significant processing adjustments achievable through the use of two distinct PEB steps with proper adjustment of the PEB conditions and the introduction of one or more delay steps following an initial PEB step. While the '262 application broadly references a plurality of PEB steps, specific adjustment of these and use of a rest step between the PEB steps are not disclosed in the effective ways taught herein. The atmosphere contacting the film can be adjusted to influence desired contrast in the film, and this has been generally known. As disclosed in the present application, a high moisture atmosphere and rest steps under very low pressure are described to effectively obtain more uniform processing through the film thickness. While the '262 patent expresses a range of process parameters, the '262 patent indicates that processing at higher pressures can facilitate desirable condensation of the irradiated film. The '262 patent exemplified application of vacuum in a post exposure delay prior to a PEB and found little effect (FIG. 9 of '262 patent). Contrary to previous expectations, the use of vacuum, i.e., low pressure, during a portion of a delay step between two PEB process steps can be effective to reduce dose-to-size, which would seem to encourage condensing the film prior to development and may encourage reactivity of irradiated film, and this is demonstrated in examples below.

As noted in the '262 patent, the relative humidity in a wafer fabrication (fab) facility is generally from about 40% to about 60% at roughly atmospheric pressure. The '262 notes that either higher or lower relative humidities can be used for processing. In the '262 patent, water is considered a potential reactive gas that can be delivered during a process step to facilitate condensation. While the '262 patent exemplified air, it did not exemplify air with elevated humidity relative to the controlled humidity generally found in a wafer fab.

In addition to the general discussion of two PEB steps in the '262 patent, a plurality of PEB steps is described in WO 2023/009336 to Tan et al. (hereinafter the '336 application), entitled “Multi-Step Post-Exposure to Improve Dry Development Performance of Metal-Containing Resist,” incorporated herein by reference. The focus in the '336 application is a first PEB with an oxygen containing atmosphere followed by a second PEB in an inert atmosphere. Of course, air has roughly 21% O₂ (or a partial pressure of roughly 160 Torr), so process steps in air effectively have a relatively high partial pressure of oxygen and, depending on the relative humidity, potentially on the order of a percent of water vapor. As noted above, the relative humidity in a semiconductor fab facility is generally controlled to 40% to 60%. As can be common in patent applications, the '336 application has a broad process description followed by asserted inventive improvements. The '336 application describes desirable embodiments as being substantially free of moisture (“In some implementations, each of the oxygen-containing environment and the inert gas environment is free or substantially free of moisture.”—paragraph [0009]) since condensation of the resist layer involves evolution toward a metal oxide structure, but this assertion neglects the realization that water vapor can facilitate organic release and achieve an appropriate film condensation, which should involve hydroxide groups since a fully oxidized tin coating can be difficult to develop. However, the '336 application does describe a potential wide range of moisture levels during processing.

The '336 application refers to de facto delay times in the context of “queue times” which are described as periods of time between process steps to allow for transfer of the wafer or adjusting conditions. For example, the irradiation can be performed in a particular chamber for that purpose, and then the wafer is moved for post irradiation processing. With respect to the queue time between irradiation and PEB, the '336 application at paragraph [0063] states that this time should be “as short as possible.” The '336 application asserts that a longer queue time between irradiation and PEB results in an increase in dose-to-size for patterning, but data presented in the '262 patent shows the opposite result. Similarly, paragraph [0072] discusses queue times between the first bake and the second bake. Again, it is described that this queue time also should be short. The handling of the wafers during the queue times does not seem to be discussed. The '336 application notes the partial pressure of oxygen contributing species which is a significant parameter for their asserted inventive embodiments. See paragraphs [0057] and [0061]. While water is listed as an oxygen contributing species, it is also noted to inhibit condensing of the film. Para [0038] of the '336 application has a broad discussion of potential pressure values without significant discussion of implications.

Post irradiation processing as presented herein can comprise process steps with enhanced humidity and delay steps can be performed under low pressure environments. These process steps can enhance contrast during subsequent development steps. Overall, post irradiation processing covers all processes involving the irradiated film between irradiation and development to form a physical image based on a virtual image created by the irradiation. Practically, this processing can involve transport of a substrate, e.g. a wafer, with the film from an irradiation module to a module for additional processing, potentially additional transport steps involving the substrate and potentially storage of the substrate/wafer. The post irradiation processing generally comprises one or more post exposure bakes and may involve rest periods under a controlled atmosphere, which can be different from the processing facility ambient.

As described further below, water can influence the processes in a few ways. Water can facilitate completion of hydrolysis of hydrolysable ligands. On the other hand, full condensation into a metal oxide involves dehydration to replace hydroxide ligands with bridging oxo ligands. However, full condensation to a metal oxide results in a material too stable for effective development. Therefore, it is desirable for condensation to be controlled and distributed relatively uniformly through the film thickness. High humidity in air still involves a large percent of molecular oxygen so that the oxygen and water can be adjusted to achieve a desired degree of condensation while achieving uniformity through the film thickness. Introduction of moisture at appropriate process times can result in sufficient penetration and diffusion of water through the film to achieve a uniform and reproducible film for development.

### Organotin Patterning Compositions, Coating and Pre-Irradiation Processing

Effective implementation of organotin patterning compositions has generally been based on deposition of organotin precursors with hydrolysable ligands in addition to a radiation sensitive organotin ligand forming a C—Sn bond. In particular, mono-organotin compounds have been found to be particularly effective. Monoorgano tin compositions can generally be represented by the formula RSnL₃, where R is an organo group and L is a hydrolysable ligand. For processing to form radiation patternable coatings, L is generally hydrolysed before or during (e.g., in-situ) deposition, and/or after deposition (e.g., in a post application bake) to result in a coating comprising a polymeric organotin oxo-hydroxo composition on a substrate wherein the Sn—R bonds remain substantially intact. As a result, a radiation patternable coating having radiation-sensitive Sn—R (Sn—C) bonds can be realized.

The hydrolysable ligand L in general can be any reasonable hydrolysable ligand, and in particular can be independently an alkoxide (—OR′), a dialkylamide (—NR′₂), an alkylacetylide (—C≡CR′), an alkylsilylamide (—N(SiR′₃)₂), or a combination thereof, wherein R′ generally is an organo group with 1 to 10 carbon atoms, optional unsaturated groups, and optional heteroatoms. Solution based coating has been particularly effectively applied with alkoxide hydrolysable ligands, and vapor deposition can be effectively applied with alkoxide or dialkylamide ligands, which generally provide sufficient vapor pressures.

The photoresist film can be heated following deposition, such as during a post-apply bake (PAB) process. Suitable PAB process temperatures and times can be at temperatures from about 25° C. to about 250° C., in some embodiments from about 35° C. to about 225° C., in other embodiments from about 45° C. to about 200° C. and in further embodiments from about 55° C. to about 180° C., or any temperature range based on any of these lower temperature values with any one of these upper temperature values. The heating for solvent removal can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of heating temperature and times within the explicit ranges above are contemplated and are within the present disclosure.

In general, the atmosphere, i.e. ambient, over the coated film during a PAB process can be inert, air or a selected vapor composition. Similarly, the pressure can be adjusted. For solution deposition embodiments, PAB can comprise completion of solvent removal. For either solution deposition or vapor deposition, the PAB can comprise completion of hydrolysis and annealing of the radiation sensitive film. To facilitate completion of hydrolysis, it is generally desirable for the ambient to comprise water vapor, and from this perspective, ambient air from the facility generally provides an appropriate atmosphere for the PAB or a portion thereof.

As noted above, the '262 patent described a post PAB delay in ambient facility air prior to irradiation. This post-PAB delay had only a small effect after a relatively long delay. In practice, there can be a delay at a fabrication facility as a wafer is transferred from a coating chamber to an irradiation chamber. Control of this process can be integrated into the process flow to achieve potential influences from the pre-irradiation processing. Following irradiation, significant changes take place related to achievement of contrast between irradiated and non-irradiated regions of the organotin film, and contrast is not mapped out prior to irradiation.

A selected thickness of the radiation patternable coating can depend on the desired process. For use in single-patterning EUV lithography, coating thicknesses are generally chosen to yield patterns with low defectivity and reproducibility of the patterning. For solution deposition, the thickness of the photoresist film generally can be a function of the precursor solution concentration, viscosity, and the spin speed for spin coating. For other coating processes, such as vapor deposition methods, the thickness can generally be adjusted through the selection of the coating parameters such as flow rates, pressures, temperatures, and so forth. In some embodiments, it can be desirable to use a thin coating to facilitate formation of small and highly resolved features in the subsequent patterning process. For example, the photoresist film can have an average thickness of no more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the film. In general, the photoresist coatings are relatively uniform to facilitate processing. In some embodiments, such as high uniformity coatings on reasonably sized substrates, the evaluation of coating uniformity or flatness may be evaluated with, for example, a 1 centimeter edge exclusion, i.e., the coating uniformity is not evaluated for portions of the coating within 1 centimeter of the edge, although other suitable edge exclusions can be selected.

Generally, photoresist coatings can be patterned using radiation. Suitable radiation sources include extreme ultraviolet (EUV), ultraviolet (UV), or electron beam (EB) radiation. For fabrication of semiconductor devices, EUV radiation can be desirable due to its higher resolution compared to UV radiation, and its higher throughput compared to electron beam (EB)-based processing. Radiation can generally be directed to the substrate material through a mask or a radiation beam can be controllably scanned across the substrate to form a latent image within the resist coating.

In general, while suitable radiation sources are those that generally provide for wavelengths that effectively absorb in the photoresist, typical radiation sources generally correspond to commercial lithography applications. For example, wavelengths most relevant to lithography include commercial EUV exposure tools (such as those fabricated by ASML) which operate at a wavelength of 13.5 nm and commercial UV exposure tools which generally operate at a wavelength of 193 nm for ArF excimer laser sources or 248 nm for KrF excimer laser sources. A person of ordinary skill in the art will understand that other absorbative wavelengths are contemplated and within the scope of the disclosure. The international standard for optics and photonics is ISO 20473:2007(E), incorporated herein by reference. This standard has the broad range of UV wavelengths from 1 nm to 380 nm, with the EUV range from 1 nm to 100 nm.

The amount of electromagnetic radiation can be characterized by a fluence or dose which is obtained by the integrated radiative flux over the exposure time. For embodiments in which EUV radiation is used, suitable radiation doses can be from about 1 mJ/cm² to about 150 mJ/cm², in further embodiments from about 2 mJ/cm² to about 100 mJ/cm² and in further embodiments from about 3 mJ/cm² to about 50 mJ/cm². A person of ordinary skill in the art will recognize that additional ranges of radiation fluences within the explicit ranges above are contemplated and are within the present disclosure.

While not wanting to be limited by theory, during exposure to radiation the radiation-sensitive Sn—C bonds are cleaved to result in an organotin material comprising a population of Sn species with reactive sites such as unsatisfied coordination environments, dangling bonds, redox-active species, radicals, and so forth. During subsequent processing and exposure to an atmosphere, such as ambient air, reactive species from the air can diffuse into the photoresist and react with the photoresist composition. In one example, H₂O can diffuse into the photoresist and can drive hydrolysis/condensation reactions to produce Sn—OH₂, Sn—OH, and Sn—O bonds and associated crosslinking between Sn centers. In another example, O₂ can diffuse into the photoresist and can drive oxidation reactions that produce Sn—OH and Sn—O bonds. In any case, the effect of reaction of the irradiation photoresist material with reactive O-containing species can lead to the material exhibiting increased metal oxide character characterized by an increased density of Sn—O and Sn—OH bonds.

It is therefore believed that the presence of H₂O, O₂, NOₓ (e.g., NO₂, NO, and other nitrogen oxides), and other polar vapors during processing of metal oxide resists, particularly after exposure to radiation, can have significant effects on the photoresist's performance, and thus it is desirable to specifically control the species present in the ambient atmospheres during post-irradiation processing of the metal oxide resist. The photoresist-coated wafer can generally be subjected to multiple ambient environments during processing because the wafer generally is physically moved (i.e., be shuttled or transported) through a set of different modules, tools, and/or containers during the lithographic process. Also, the conditions within a particular module with suitable pumps and/or inputs. For conventional lithographic processing, the ambient environment for the majority of these process steps is not controlled beyond control of the larger room's (e.g., the wafer fab's) ambient environment and/or beyond air filtering and removal of certain airborne contaminants, and which may not be sufficiently effective at removing reactive species. The manipulation of post-irradiation processing prior to image development can be manipulated to achieve desired results.

### Processing Steps and Controlled Ambient Conditions

The general procedure is summarized above in the context of FIG. 1. The significant processing features between irradiation and development are discussed in the next section. As noted above, control of the composition of the ambient atmosphere and the pressure can significantly influence film uniformity and degree of condensation. A highly condensed film can be relatively resistant to gaseous penetration and diffusion. The irradiation process also leads to radiolysis of Sn—C bonds and prepares further species susceptible to radiation induced thermolysis of Sn—C bonds, which takes place during the post exposure bakes. The loss of organic species resulting from radiation induced thermolysis contributes to the contrast between irradiated and non-irradiated regions of the film, and to moderating the rate of condensation can be used to correspondingly influence the efficacy of radiation induced thermolysis. Excessive heating can result in thermolysis fragmenting tin-carbon bonds whether or not irradiated, which results in a loss of contrast. Thus, excessive heating is avoided to correspondingly avoid thermolysis without radiation induction, which can result in a loss of contrast.

Radiation-induced cleavage of the Sn—C bonds results in the formation of polar species comprising Sn—OH and Sn—O bonds, and the formation of these polar species can be further promoted during post-exposure heating processes as the exposed material reacts with ambient air and humidity. Tin-carbon bond cleavage is the main mechanism for generating contrast between irradiated and non-irradiated regions. Applicant has observed that radiation induced thermolysis is a significant mechanism for organic species outgassing from the irradiated films. Thus, control over the post-irradiation processing can be a significant factor in achievement of desired film properties, including at least increasing EUV sensitivity, enhancing contrast, sharpening boundaries, and achieving uniformity through the film thickness, based on design of thermal treatments, delay steps and atmosphere over the film during these process stages.

For these reasons, control of the ambient environment during and between each step of processing can be desirable for the processing of metal oxide-based photoresists. During transport, storage, of the wafer in the process flow, the ambient environment that the wafer is exposed to can significantly influence the ultimate performance of the photoresist and can contribute to undesirable variability in outcomes. The ambient environments during transport, resting, and/or storage of the wafers can be controlled with respect to desired performance. The start of the process sequence can be considered the coating process. Irradiation can be performed in a specialized chamber, so that transport can involve movement into and out from the irradiation chamber and possibly between other process chambers. Resting and storage are generally purposefully done to achieve certain effects, and post irradiation resting is described in detail below.

In one example, it can be desirable to tailor specific ambient conditions that the wafer is exposed to between PEB steps. In another example, it can be desirable to tailor specific conditions that the wafer is exposed to after a PAB step and prior to EUV exposure. A general process flow with explicit processing steps with potential rest steps interwoven between each is shown in FIG. 1, which is discussed further above. Specific ambient conditions can include inert environments (e.g., N₂, Ar, or other noble gases), controlled humidity environments, controlled oxygen-rich environments, and controlled NOₓ environments. The pre-irradiation processing is described further above. EUV irradiation is generally performed in a specially designed module under low pressure to allow for desired patterning with the EUV radiation. While further processing could be performed in the irradiation chamber, due to the relatively high cost of the EUV irradiation components, further processing is generally performed by moving the irradiated wafer to a different process module. Resting steps may or may not be performed in the same module as thermal heating steps. Process equipment for transferring and heating wafers under a controlled atmosphere are commercially available from at least Tokyo Electron Limited (such as Lithius Pro™ line), and LAM Research. See, for example, the '336 application.

The controlled ambient environments can generally be provided by a chamber, module, or similar process tool(s) wherein the wafer is handled following exposure to EUV radiation. For example, controlled environments can be provided within wafer tracks that handle and shuttle wafers between various process steps. In some cases, the controlled environments can be provided by wafer carriers or other containers during storage and/or transport of the wafers. Generally, the ambient environment can be static or can be dynamic (i.e., performed with a flow of gas). Generally, the controlled ambient is also at a controlled pressure. Adjustment of the pressure generally involves appropriate gas flow, and the flow can be maintained with adjustment to maintain the pressure or can be static once the target pressure is achieved. Correspondingly, reduction of pressure can involve pumping gas from the chamber, and flow can be used to adjust the composition of the ambient as the pressure is reduced or maintained. The transportation and resting processes can be engineered and managed to ensure the wafer remains in a desired ambient environment(s) at each stage throughout the lithographic process.

The controlled ambient environments can generally be either static or dynamic. A static environment can include a sealed environment, such as during storage or during a resting step, where gas is charged into the environment to achieve a desired partial pressure of gas components and overall pressure. A static environment can be beneficial for wafers stored for relatively long periods of time, and inert environments can be particularly desirable of static environments. A dynamic environment is one where conditions can change over time or be manipulated as per the target conditions of the process and can typically be achieved by maintaining a flow of gas within the process tool. The type of gas, its flow rate, its pressure, and other parameters can be adjusted to create the desired dynamic environment, and thus precise control over the conditions to which the wafer is exposed. Whether static or dynamic, the ambient environment is an important aspect of the process and can play a substantial role in determining the patterning performance of the metal oxide-based resist, making its proper management a priority in the process.

In one embodiment of the invention, the semiconductor wafer, coated with the photoresist material, is subjected to an inert ambient environment during the interval between the post-apply bake (PAB) process and the exposure to extreme ultraviolet (EUV) radiation. The inert ambient environment, which can be composed of nitrogen (N₂), noble gases such as argon (Ar), or other similar gases, serves to provide a stable environment that prevents unwanted reactions from occurring within the photoresist material. By carefully controlling the ambient environment during this interval, it is possible to improve the reproducibility of photoresist patterning by mitigating potential reactions of the photoresist with other ambient species which may be present in any uncontrolled ambient environment. In this way, any variability resulting in the delay between PAB and EUV exposure of multiple wafers can be minimized. The strategic approach of introducing a controlled inert ambient environment between the PAB and EUV exposure is a novel aspect of the present disclosure and contributes to the optimization of the lithographic patterning process.

As noted herein, the objectives of post-irradiation processing are to effectuate removal of organics from irradiated section of film and correspondingly allow for condensation of the tin oxo-hydroxo network without excessively oxidizing the non-irradiated material. Thus, the processing aims to achieve a certain degree of balance. While heat can significantly influence the processing, the use of certain gases can influence the reactions with perhaps a lower reliance on heat. See, for example, the '262 patent. Water can influence material properties in various ways. For example, while not wanting to be limited by theory, water can provide OH groups and general reactive functionality that may catalyze reactions of high energy organic species formed from the irradiation, such that organics can be more readily cleared from the irradiated film. In this way, the tin oxo-hydroxo network can be further established. On the other hand, further condensation of the tin film generally involves dehydration—(2 SnOH→Sn—O—Sn+H₂O)—so that water vapor can tend to inhibit this dehydration step or tend to shift the equilibrium in the opposite direction towards uncondensed tin species. On the other hand, the partial pressure of water at room temperature is relatively low, so even in humid air, the partial pressure of oxygen is significantly greater than the partial pressure of water. The relative humidity can then be a convenient adjustable parameter for tuning film processing.

In one embodiment, the wafer can be subjected to an inert controlled ambient environment immediately after exposure to EUV radiation and prior to a first PEB. The inert ambient environment can mitigate reaction of the irradiated photoresist with reactive ambient species, such as H₂O, O₂, and/or NOₓ in an otherwise uncontrolled (in the sense of moderately controlled fab air supply) ambient air supply in a conventional process. The concentrations of these reactive ambient species can fluctuate with time and may lead to undesired temporal variability in photoresist performance. It can therefore be desirable to remove the effects of fluctuating reactive species by subjecting the wafer to an inert environment immediately after EUV exposure and prior to the first PEB process. Inert environments can generally include one or more inert gases such as N₂, Ar, other noble gases, and mixtures thereof that are essentially unreactive with the photoresist. The inert gases can be essentially free of humidity. In some embodiments, the wafer may be subjected to the inert environment during the transport of the wafer (i.e., shuttling) between the EUV exposure source and the PEB environment. In some embodiments, the inert environment can be provided by the modules, compartments, and similar avenues that the wafer is shuttled through between process steps. Particular device production can be configured around a particular equipment set up that may or may not involve periods of storage separate from a production track and corresponding tools. The configuration may influence the practicality of longer rest steps, although moderate rest steps can be accommodated and generally can provide desired effects. The manipulation of the ambient during a rest step may be able to achieve the effects of a longer rest step in a shorter period of time. In some embodiments, the wafer can be subjected to the inert environment during physical transport of the wafer and/or during storage of the wafer between processing steps wherein the inert environment is provided by or within a wafer carrier or other container known by those of ordinary skill in the art, such as a FOUP (Front Opening Unified Pod).

As noted above, the '262 patent describes a post-irradiation pause prior to a PEB under ambient atmosphere. The effects on the critical dimension are significant after a period of time. In addition to adjusting the processing during the PEB and following up until the development step, a consistent delay step can be used between irradiation and a post exposure bake. Generally, whether or not the delay is performed in an ambient atmosphere different from facility ambient, it can be desirable to have a consistent delay time to introduce increased uniformity. In some embodiments, the delay time can be at least about 15 minutes, in further embodiments at least about 20 minutes, in additional embodiments from about 25 minutes to about 8 hours, and in some embodiments from about 30 minutes to about 4 hours, although generally longer times generally provide acceptable results, but long occupation of storage space may increase process costs. It can be desirable for processing of multiple wafers to have these times refer to average process times, and variation of delay times for a particular wafer to be within about ±25% and in further embodiments within about ±15% of the average for a plurality of wafers undergoing the comparable process and patterning. A person of ordinary skill in the art will recognize that additional ranges of times and time variation within the explicit ranges above are contemplated and are within the present disclosure.

In one embodiment, the wafer can be subjected to a high humidity environment after exposure to EUV radiation. The wafer can be introduced to the high humidity environment at various points after EUV exposure, but particularly beneficial effects can be achieved by resting the wafer in a high humidity environment prior to and/or in-between PEB process steps. In an otherwise uncontrolled ambient air supply in a conventional process, the concentrations of reactive ambient species such as H₂O and/or O₂ can fluctuate with time and may therefore lead to undesired temporal variability in photoresist performance. It can therefore be desirable to remove the effects of fluctuating reactive species by subjecting the wafer to a controlled high humidity environment. The high humidity environment can drive reaction of the irradiated photoresist with a controlled concentration H₂O and can lead to a more controlled and reproducible photoresist film composition. Exposure of the irradiated material to a controlled high humidity environment without additional heating can help drive diffusion of H₂O, O₂, and/or other O-containing species through the irradiated regions of the resist without driving significant densification via condensation. In some embodiments, the controlled high humidity environment can have a relative humidity (RH) of at least about 60%, at least about 61%, at least about 65% in additional embodiments, at least about 70% in some embodiments, and least about 90% in further embodiments. The relationship between the relative humidity and partial pressure of water is significantly dependent on temperature since warmer air can hold more moisture. Thus, if high humidity gas at room temperature is heated, the relative humidity of the same heated gas (e.g., air) would be significantly less unless moisture is added. The wafer can be subjected to a high humidity environment for from at least about 10 seconds to about 60 minutes in some embodiments, for from about 20 seconds to about 30 minutes in some embodiments, for from about 30 seconds to about 10 minutes in some embodiments, and for from about 1 minute to about 5 minutes in further embodiments. A person of ordinary skill in the art will recognize that additional ranges of relative humidity and durations within the explicit ranges above are contemplated and are within the present disclosure.

After irradiation and optional systematic post irradiation delay step, the substrate with irradiated film, e.g. a wafer, is subjected to post irradiation heating and associated processing leading to image development. Advantageous application of multiple heating steps and delay steps are described in the following section.

### Multiple PEB+Rest Processing

After exposing the metal oxide resist film to EUV radiation, a PEB process is generally performed to drive radiation induced thermolysis and/or reaction of H₂O and/or other O-containing species with the resist material in the irradiated regions to drive an increase in contrast between the irradiated and non-irradiated regions. Water diffusing into the irradiated material is believed to react quickly with the heated resist matrix to drive hydrolysis/condensation reactions. It is not clear whether or not water plays a direct role in the radiation induced thermolysis, but water would seem to play a role in the reorganization of the resulting tin oxo-hydroxo network by providing O and OH sources. While not wanting to be limited by theory, during the PEB process and after a specific amount of time, the diffusion of water and/or other O-containing species into and through the resist film can be considered a rate-limiting step for the matrix reorganization into a stable, uniform material ready for effective development.

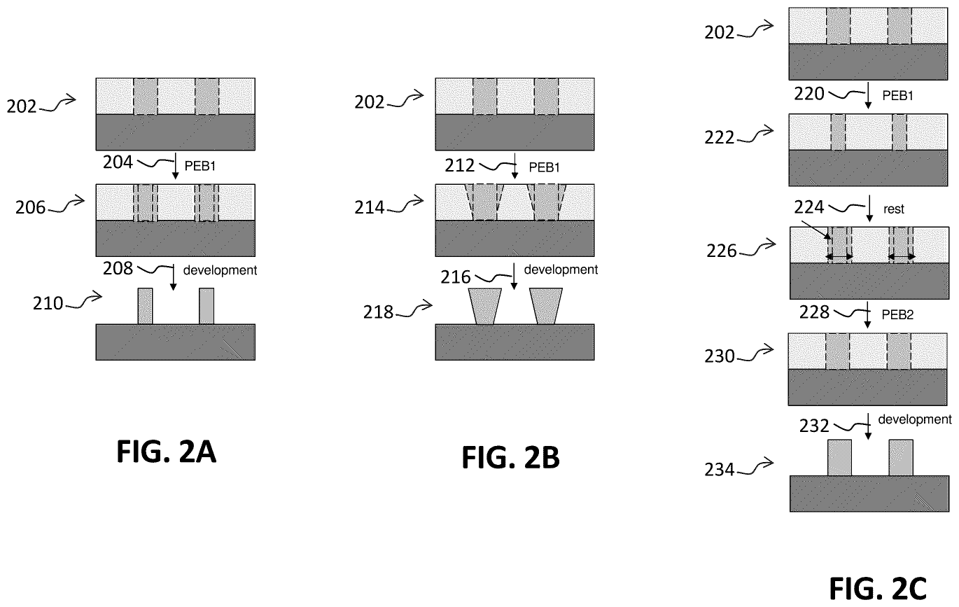

FIG. 2A schematically depicts a cross-sectional view of an EUV-irradiated metal oxide photoresist with a latent image 202, which is subjected to relatively short post exposure bake (PEB) 204 to form baked latent image 206, which is then developed 208 to form pattern 210 having smaller-than-desired features sizes. FIG. 2B schematically depicts a cross-sectional view of an EUV-irradiated metal oxide photoresist with a latent image 202, which is subjected to relatively long post exposure bake (PEB) 212 to form baked latent image 214, which is then developed 216 to form pattern 218 having T-topping of the features.

During the irradiation process, especially with EUV, radiation intensity is not consistent with a desired step function at pattern edges, but for many reasons results in a Gaussian-like distribution of radiation intensity with a peak near the center of an irradiated region relative to a target boundary and falling off significant crossing a sharp decrease beyond the target boundary. As depicted in FIG. 2A, a consequence of required reaction with water diffusing through the exposed regions that is effective to drive metal oxo-hydroxo formation suggests that for short duration PEB processing the water supplied from the atmosphere cannot adequately reach portions of the film thickness involving greater diffusion times, and the dimensions of the resulting pattern can be smaller than desired. Portions of the film receiving lower amounts of radiation may involve longer reaction times to effectuate radiation induced thermolysis and corresponding network formation. Short PEB times do not provide enough time for an extended metal oxide hydroxide network to form and thus can result in an increased dose-to-size (DtS) for a given feature size. Conversely, for long-duration PEB processing as illustrated in FIG. 2B, the more strongly irradiated portions of the film, more readily reorganize with respect to the oxo-hydroxo network, so the equilibrium adjustment of the oxo-hydroxo network propagates from the center of the pattern. The supply of water to drive the network adjustment diffuses from the surface so if diffusion becomes rate-limiting, this can result in T-topping due to the top of the irradiated resist reacting with absorbed H₂O before the molecules can diffuse to the bottom of the film. For high flow environments where water can be continually replaced at the surface of the wafer, hydrolysis/condensation reactions can continue to occur near the surface of the resist at a higher rate than the bottom of the resist due to the limited ability of water and/or O-containing species to diffuse before reacting. Thus, it can be inefficient to attempt to compensate for the T-topping through adjustment of a single PEB process condition. As described herein, and as shown in FIG. 2C, a process comprising multiple PEB processes can be used to allow for improved diffusion of H₂O, O₂, and/or other O-containing species through the thickness of the resist.

Referring to FIG. 2C, a multi-step PEB process can be beneficial and offers added degrees of control over the processing that can provide an improvement over a single PEB process. FIG. 2C schematically depicts a cross-sectional view of EUV-irradiated metal oxide photoresist with a latent image 202, which is subjected to first post exposure bake (PEB) 220 to form first baked latent image 222, which is then subjected to rest 224 to form rested latent image 226. Rest 224 can allow for water and/or other O-containing molecules to diffuse into the resist film and while the temperature is too low for further significant hydrolysis/condensation to occur, as shown by the arrows. Additionally or alternatively, a portion of a rest period can comprise application of low pressure, which can be effective to facilitate degassing of organics and other by products of the reactions involved in oxo-hydroxo network reorganization. Exemplified rest periods between PEB processes can comprise segments under low pressure and other segments over a higher pressure ambient. Second post exposure bake (PEB) 228 can then be performed to further drive hydrolysis/condensation within the resist, and therefore allowing for larger CDs at the same EUV exposure dose while also improving the patterned resist profile and reducing pattern collapse. Baked/rested/baked latent image 230 depicts the larger CDs as compared to the CDs depicted in latent image 222. This process, e.g., a bake followed by a rest period, can be generally repeated in a cyclic process if desired. As further depicted in FIG. 2C, baked/rested/baked latent image 230 can then be developed 232 to form pattern 234 having enhanced profiles of features as compared to patterns 210 and 218.

The one or more PEBs can generally be conducted at a range of temperatures that promote the desired hydrolysis and condensation reactions without causing adverse effects on the resist profile. In general, suitable PEB temperatures are those that do not result in significant loss of chemical contrast between the irradiated and non-irradiated regions, such as due to thermolysis of Sn-C bonds in non-irradiated regions which can result in loss of organic components and a loss of developer solubility. In some embodiments, a first PEB can be performed at temperatures from about 45° C. to about 220° C., in additional embodiments from about 50° C. to about 200° C., in other embodiments form about 55° C. to about 190° C., and in further embodiments from about 60° C. to about 175° C. A post exposure heating step can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure.

Heating can be accomplished using a heater built into a wafer support, using radiative heating, such as an infrared lamp, using thermal convection, or based on some reasonable combination thereof and suitability for the process environment. Thermal convection can be accomplished through heaters in the module wall and/or by heating a gas flow through the chamber. The mechanism for the thermal delivery can be determined generally based on the module design of the equipment, which is adapted accordingly. Similarly, cooling taking place after terminating the heating may be influenced by the module design and generally does not significantly influence the results. Cooling can also be accomplished in whole or in part by cooling the wafer support.

The first PEB serves to drive initial hydrolysis/condensation processes that densify the irradiated material. After exposure to radiation, water and/or other O-containing species can diffuse into the irradiated regions of the resist. In the absence of heating the diffused species can migrate through the film without participating in significant hydrolysis/condensation reactions, and the concentration of water and/or O-containing species can move towards saturation throughout the thickness of the film. During the first PEB the heating promotes hydrolysis/condensation reactions with water and/or O-containing species that have thus diffused into the film. During the PEB steps, the atmosphere contacting the irradiated film as well as the pressure can be adjusted. In particular, the ambient atmosphere can be air, air with adjusted humidity levels, inert gas, or vacuum, i.e. low pressure. As noted above, the possibility of introducing alternative reactive gases during a PEB step have been discussed. To provide desired water or other oxygen containing species, a first PEB step can be performed under air, which may or may not be enhanced with respect to relative humidity. This process can be performed at the atmospheric pressure at the fabrication facility interior, although adjustments to the pressure can be made using gas flow over reasonable ranges.

Following the first PEB, the resist film can then be rested in a delay step to allow for additional oxo-hydroxo network development prior to further processing. As used herein, rest and delay may be used essentially interchangeably to refer to steps between other process steps. Results below clearly demonstrate that the ambient during such a rest step can significantly influence development of the image. To take advantage of this rest processing, it can be desirable to further subdivide the rest step to exhibit different ambient atmospheres and/or pressures during the rest step. With respect to the ambient atmosphere, it can be desirable to have a high humidity ambient to provide water that can diffuse through the film during the rest period so that it is available during a subsequent PEB step.

Rest steps may involve cooling from a bake step, and cooling may be gradual and may or may not be encouraged through blowing of cool air or other cooling processes. The pressure and atmosphere contacting the irradiated film during the rest step can influence significantly the subsequent processing. The range of process conditions during a rest step are described in detail below. In general, a resting step can be at least about 0.1 minute, in further embodiments, at least about 1 minute, in additional embodiments from about 10 minutes to about 5000 minutes or more, in other embodiments from about 12 minutes to about 1500 minutes, and in some embodiments from about 15 minutes to about 1000 minutes, as well as any ranges formed with any of these lower limits combined with any one of these upper limits. The full rest step times can be subdivided into two, three, four or more sub-steps involving a change in ambient environment, such as changes in the pressure and/or composition of the atmosphere. Longer rest steps may take place with the wafer in a storage compartment, such as a front opening unified pod (FOUP), which generally stores wafers in a sealed configuration with fab ambient air, though wafer storage containers can be used wherein the ambient environment within can be specified and controlled, such as with clean dry air, inert gasses, humidity-controlled atmospheres, and the like. While the subdivision or rest times can be performed generally in any desired increments, in some embodiments, each increment can be influenced by the process conditions. Variations in process conditions that involve deviations from facility ambient, such as low pressure or high moisture, are generally performed in a process module, and equipment constraints generally limit such processes to relatively modest amounts of time, such as an hour or less and in further embodiments from about 0.1 minutes to about 30 minutes. A low pressure rest step, such as below about 150 Torr, or a high moisture rest step with a relative humidity of at least about 65% is generally placed before a longer rest step under a fixed ambient, such as facility atmospheric pressure and air composition. After completion of a heating step, a relatively shorter rest can take place under facility ambient air prior to exposure to a significant variation in process ambient, such as low pressure or high moisture, and the relatively shorter rest step generally can be from about 0.1 minutes to about 30 minutes. A person of ordinary skill in the art will recognize that additional ranges of rest time or rest time increments within the explicit ranges above are contemplated and are within the present disclosure.

A delay step after a PEB step has been found to potentially significantly influence subsequent development and patterning performance. The delay step can be further subdivided to provide different environments during different portions of the delay step. As noted above, this process division can be helpful since longer rests would generally, although not necessarily, be performed in a different structure than a module used to provide a particular ambient that is altered significantly relative to facility ambient, such a low pressure or high humidity. Following delay, a second PEB step can be performed, development can be performed, and/or steps can be repeated, such as a further delay step after a second PEB step and possibly further additional repeated heating and delay steps. During a delay step, the ambient atmosphere and pressure exposed to the film can be adjusted, and the delay step can be effectively divided to provide distinct effects during the delay step.

A delay step can be characterized by total time, pressure, atmosphere over film, and any subdivisions of the delay process. It has been found that a low pressure, such as a vacuum, environment is applied to the film during a post-PEB delay step can be effective to lower dose-to-size. Without wanting to be limited by theory, the low pressure environment may facilitate dehydration and possibly organic removal from the irradiated film during the delay step. If other portions of the delay involve exposure to atmospheres with water vapor present, the water can further influence the evolution of the oxo-hydroxo network.

During portions of a delay step in which water is available in the atmosphere, more water and/or O-containing species can diffuse into the film without driving significant hydrolysis/condensation reactions. The rest period allows for water and/or O-containing species to diffuse through the thickness of the film and move the material towards saturation such that these species are available for hydrolysis/condensation reactions during a subsequent PEB. In some embodiments, the wafer can be rested in a normal air ambient environment. In other embodiments, the delay step can comprise a low pressure. In some embodiments, the wafer can be rested in a high humidity-controlled environment. In some embodiments the resist film can generally be rested between PEBs in a high humidity environment or a low pressure environment for at least about 0.1 minute, in further embodiments from about 0.2 minutes to about 300 minutes, in additional embodiments from about 1 minutes to about 60 minutes, in other embodiments form about 2 minutes to about 30 minutes or any range based on any of these upper limits with any one of the lower limits. A person of ordinary skill in the art will recognize that additional ranges of resting durations within the explicit ranges above are contemplated and are within the present disclosure. If desired, a high humidity rest step can be a fraction of a longer overall rest step or not, as summarized above.

In some embodiments, at least one of the PEB steps can be performed in a high-humidity environment. The high-humidity environment can provide for a high supply of water available to react and drive hydrolysis/condensation reactions during heating, and therefore promoting the formation of a metal oxide hydroxide network. The PEB can be conducted in an environment with a relative humidity (RH) of at least about 60%, at least about 61% in some embodiments, at least about 65% in other embodiments, at least about 70% in some embodiments, and least about 90% in further embodiments. A person of ordinary skill in the art will recognize that additional ranges of relative humidity within the explicit ranges above are contemplated and are within the present disclosure.

In some embodiments, the resist can be rested in a high-humidity environment, which may be part of a longer total rest step. The high-humidity environment can enhance diffusion of water into the resist film by increasing the concentration gradient between the ambient and the film and can therefore reduce the resting time needed for the water within the resist film to reach saturation. The resist can be rested in an environment with a high relative humidity (RH) of at least about 60%, at least about 61% in some embodiments, at least about 65% in other embodiments, at least about 70% in some embodiments, and least about 90% in further embodiments. A person of ordinary skill in the art will recognize that additional ranges of RH within the explicit ranges above are contemplated and are within the present disclosure. In other embodiments, a high or low pressure, such as a vacuum pressure, can be applied during a delay step or a portion thereof. Suitable pressure ranges are provided below.

The PEB+ resting processing can take advantage of the interplay between hydrolysis rate and diffusion distance. As the temperature increases, the rate of hydrolysis/condensation generally increases which in turn reduces the distance water and/or other O-containing species can diffuse without reacting, which can result in incomplete hydrolysis/condensation reactions near the bottom of the film. By performing a multi-step process comprising a first PEB step and a rest step, a more uniform resist profile can be achieved by enabling more water and/or other O-containing species to reach the bottom of the irradiated resist and possibly by allowing slower radiation induced thermolysis to proceed more to completion, to drive more effective hydrolysis/condensation reactions in a second or subsequent PEB.

The second PEB serves to densify and condense the irradiated regions of the photoresist. Conducting a first PEB and a rest step can induce chemical changes in the irradiated regions of the photoresist that can promote densification in a second PEB process. By resting the photoresist after a first PEB process wherein water and/or other O-containing species are allowed to migrate into the irradiated material, a second PEB can drive further reactions to condense the irradiated material further. Similarly, subjecting the irradiated photoresist to a low-pressure environment after a first PEB may allow for removal of thermolyzed and volatile organic species from the irradiated regions, and which can therefore allow for better densification of the irradiated regions during a second PEB. In some embodiments, a second PEB can be performed at temperatures similar to the first PEB. In some embodiments, a second PEB can be performed from about 45° C. to about 250° C., in additional embodiments from about 50° C. to about 220° C., in other embodiments from about 55° C. to about 200° C. and in further embodiments from about 60° C. to about 175° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure.

In some embodiments, the first PEB temperature and time can be different than the second PEB temperature and/or time. In some embodiments, the first PEB can be performed at a lower temperature than the second PEB. In some embodiments, the first PEB and the second PEB can be performed at the same temperatures. In some embodiments, the first PEB can be performed at a higher temperature than the second PEB. The times of the first PEB and the second PEB can be independently selected to yield desired effects from the PEB. If the temperatures in a first PEB and a second or other subsequent PEB are different, the difference in temperature can be at least about 5° C. and in further embodiments at least about 10° C. A person of ordinary skill in the art will recognize that additional ranges of temperature differences are contemplated and are within the present disclosure.

In some embodiments, the rest step and/or PEB can be performed under a controlled atmosphere with a specific composition of gases to further influence the reaction dynamics. For example, the rest step and/or PEB atmosphere can include a mixture of an inert gas and a controlled amount of water vapor to precisely regulate the humidity levels during the bake. This can be particularly beneficial in achieving a uniform distribution of hydrolysis and condensation reactions throughout the resist film. Some further examples of performing a PEB under controlled atmospheres is described in U.S. patent application Ser. No. 17/188,679 by Telecky et al., entitled “Process Environment For Inorganic Resist Patterning”, incorporated herein by reference.

In some embodiments, the wafer can be subjected to a reduced pressure environment, such as a vacuum, during a rest step and after conducting a PEB. The reduced pressure environment can promote dehydration, removal of organics, and condensation of the metal oxide resist material without providing thermal energy. The pressure of the reduced pressure environment can generally be below atmospheric pressure or about 760 Torr at sea level. Since most facilities are above sea level, the actual average atmospheric pressure is slightly less than standard atmospheric pressure (760 Torr), and weather induces further temporal changes. Also, ventilation systems can be set to maintain a slight negative pressure relative to the outside pressure to control relative flow of gases into or out from the facility. Within a process chamber, a slight overpressure can be maintained to turn over the gases in the chamber. A person of ordinary skill in the art will recognize these pressure issues, and from a practical perspective, pressures from about 700 Torr to about 800 Torr can be roughly considered atmospheric pressure. To differentiate a lower pressure environment from a close to atmospheric pressure environment, pressures above 600 Torr can be considered not a low pressure environment. In some embodiments, the reduced pressure environment can be a low vacuum environment having a pressure from about 600 Torr to about 25 Torr, and in further embodiments from about 150 Torr to about 25 Torr. In some embodiments, the reduced pressure environment can be a medium vacuum environment having a pressure from about 25 Torr to about 1×10⁻³ Torr, in further embodiments from about 25 Torr to about 1 Torr and in alternative embodiments from about 1 Torr to about 1×10⁻³ Torr. In some embodiments, the reduced pressure environment can be a high vacuum environment having a pressure from about 1×10⁻³ Torr to about 1×10⁻⁹ Torr. A person of ordinary skill in the art will recognize that additional ranges of pressures within the explicit ranges above are contemplated and are within the present disclosure.

The PEB and/or rest steps can be performed in conjunction with a real-time monitoring system that can measure the concentration of water, O₂, CO₂, NOₓ, and/or other gases within the process environment. Commercial real time gas monitoring equipment for use in a semiconductor processing facility are available, for example, from Thermo-Fisher Scientific or Nikira Labs. Such monitoring systems can provide feedback useful for the adjustment of the wafer's process environment allowing for dynamic adjustments to the ambient atmosphere based on real-time data. This ensures that the ambient environment remains stable and consistent throughout the process, leading to improved photoresist performance and reduced variability in the lithographic outcomes. These systems can typically consist of several components that work together to ensure the process environments are maintained within desired parameters for optimal photoresist performance. For example, gas analyzers and sensors can be used to detect and quantify concentrations of specific gases within the ambient atmospheres of specific process tools. Similarly, humidity sensors can also be used to provide real-time measurements of the relative humidity within an ambient environment. In general, the various sensors can be integrated with control systems that are responsible for processing the sensor data and for adjusting the process environments by regulating the flow of gases, temperatures, and pressures based on the sensor feedback. Data acquisition systems can be employed to collect the sensor data and relay it to a processing unit that can analyze the data and determine whether the ambient process environment is within the specified parameters. If deviations are detected, the system can trigger corrective actions to bring the environment back to the desired conditions. Suitable corrective actions can comprise, for example, increasing gas flow through the chamber to eliminate undesired build up, adjust humidity levels through providing more or less moisture, or the like. Overall, the use of real-time monitoring systems in the process environments helps to achieve desired control over the ambient conditions, which is particularly beneficial for the processing of metal oxide-based photoresists where the presence of water vapor, oxygen, and other gases can have a substantial impact on the photoresist's performance.

In some embodiments additional PEB steps and rest steps can be performed in a cyclic process where the process comprises heating the resist in a PEB step and then resting the resist in a rest step in repeated as desired. In general, the final PEB does not need to be followed by a rest step and can instead be directly followed by further processing such as development, etch, and so forth, although equipment response times provide a lower limit on times between process steps.

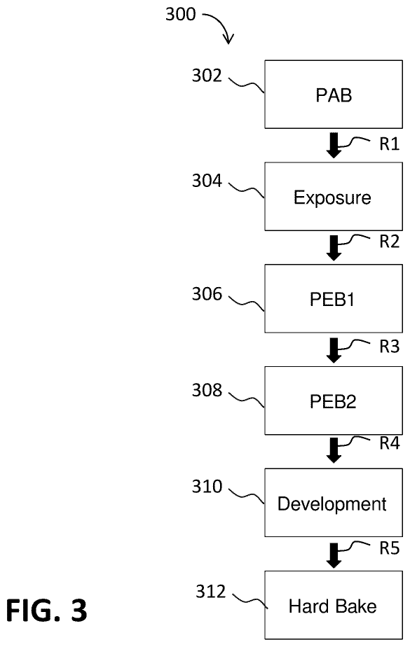

In general, one or more specifically controlled rest steps can be performed between individual steps in the lithographic patterning process wherein the controlled rest step includes exposing the resist-coated wafer to a controlled atmosphere. The controlled atmospheres can generally comprise reactive gases such as H₂O, O₂, NOₓ, and also may comprise inert compositions, or the controlled atmosphere can comprise a reduced pressure, such as no more than about 150 Torr. To achieve process uniformity between different wafers, it is generally desirable for rest steps to be uniform between different wafers, although for longer rest times, plateaus can be reached so that time variations may no longer be as significant. For rest times shorter than 300 minutes, it can be desirable for variation in rest times to be no more than about ±10%. Some illustrative process flows are shown in FIG. 3 with each potential rest step labeled from R1 to R5 and with suitable controlled ambient environments listed for each one, wherein A=inert, B=humidity controlled, C=NOₓ controlled. Referring to FIG. 3, the general process flow (300) generally comprises performing a post application bake (PAB) 302; irradiating the film 304; a post irradiation processing, which can comprise a post exposure bake (PEB) 306 and an optional second post-exposure bake 308; development 310; and post development processing, such as a hard bake 312, in which various optional rest or delay steps (R1-R5) are possible along the process flow.

| Rest | Suitable Controlled |
|---|---|
| Step | Atmospheres |
| R1 | A, B |
| R2 | B, C |
| R3 | B, C |
| R4 | A, B |
| R5 | A |

### Development

Following performing post-irradiation process, which generally involves one or more PEB and controlled rest steps, development of the image involves the contact of the patterned coating material including the latent image to a developer composition in liquid or vapor form to remove either the un-irradiated coating material to form the negative image or the irradiated coating to form the positive image. Irradiated regions of organotin oxide hydroxide coatings are generally hydrophilic and are thus soluble in aqueous acids or bases and insoluble in organic solvents; conversely, non-irradiated regions are generally hydrophobic and are thus soluble in organic solvents and insoluble in aqueous acids or bases. For negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. Some useful developer compositions for these organotin oxide photoresists have been described in published U.S. Patent Application No. 2020/0326627 to Jiang et al., entitled “Organometallic Photoresist Developer Compositions and Processing Methods”, incorporated herein by reference.

It has also been discovered that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Provisional Application 2023/0100995 by Cardincau et al. (hereinafter the ';995 application), entitled “Method for Enhancing Development Contrast and Apparatuses for Processing Substrate”, both of which are incorporated herein by reference. A development approach presented in the '995 application is exemplified below. In such dry development processes, development can be achieved by exposing the coated, irradiated substrate to a plasma or a thermal process while flowing a gas comprising a small molecule reactant that facilitates removal of irradiated or non-irradiated regions. The dry development can comprise contacting the organometallic composition with a vapor of a carboxylic acid in an isolation chamber at a partial pressure from about 0.1 Torr to about 50 Torr, at a temperature from about 100° C. to about 250° C., with a flow rate from about 0.1 sccm to about 5000 sccm (standard cubic centimeters per minute), at a temperature from about −45° C. to about 250° C. to remove the non-irradiated portion of the irradiated film. Following development, a rinse step can be conducted if desired to further remove undesired material from the pattern, and such methods have been described in published U.S. Patent Application No. 2020/0124970 to Kocsis et al., entitled “Patterned Organometallic Photoresists and Methods of Patterning,” incorporated herein by reference.

After completion of the development step including any optional rinses, the photoresist and underlayer materials can be heat treated to further condense the material and to further dehydrate, densify, or remove residual developer from the material. This heat treatment can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the baking of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiments for about 2 minutes to about 1 hour, in further embodiments from about 2.5 minutes to about 25 minutes. The heating may be performed in air, vacuum, or an inert gas ambient, such as Ar, other noble gas, or N₂. A person of ordinary skill in the art will recognize that additional ranges of temperatures and time for the heat treatment within the explicit ranges above are contemplated and are within the present disclosure. Likewise, non-thermal treatments, including blanket UV exposure, or exposure to an oxidizing plasma such as O₂ may also be employed for similar purposes.

After a final heat or non-thermal treatment to solidify the patterned resist material, the substrate can then be subjected to one or more etch steps to provide for removal of photoresist residues, transfer of the resist pattern into the substrate, stripping of the photoresist, and so forth. Further processing can be repeated to complete device formation in a layered structure assembled on the substrate.

### EXAMPLES

### Example 1: Processing with Rest Step between Post-Exposure Baking

This example is meant to illustrate the effect of multiple PEB processes with a rest period between each bake compared to conducting two PEB processes without a rest period between the bakes.

Silicon wafers having a 10 nm layer of spin-on-glass (SOG) were used as the substrates. The wafers were coated with approximately 26 nm of a commercial organotin photoresist (Inpria YATU1011 resist). The wafers were then baked at 100° C. for 60 s and then exposed to EUV radiation using an ASML NXE3400 exposure tool to form an array of line/space patterns at different doses across the wafer.

After exposure each wafer was subjected to a first PEB wherein the wafers were baked at 180° C. for 60 seconds. The wafers were then rested for various times (e.g., no rest time, 30 seconds rest time, 1 hour rest time) prior to being subjected to a second PEB at 200° C. for 60 seconds. After completion of the second PEB process, the wafers were then developed and subject to a final bake at 150° C. for 60 seconds. SEM images were collected for each dose and images were fed into a software package from Stochalis to count the number of defects per image. The post irradiation processing was performed under air with standard facility humidity of 40%-45%. A defect limit of 10 defects/image was used to find the lower cliff limit which is the minimum critical dimension (CD) where no more than 10 defects/image were observed.

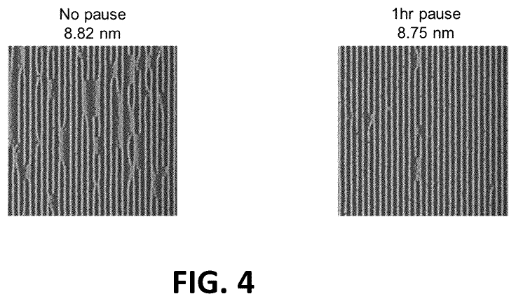

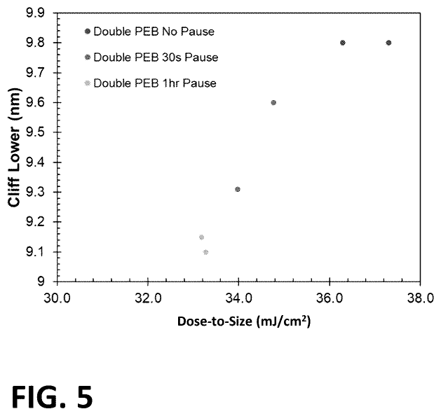

FIG. 4 shows two representative SEM images at similar CD values near the lower side process window (about 8.8 nm CD) for wafers processed with and without a resting step between PEBs. The image on the left was processed without a resting step between the PEBs. The image on the right was processed with a 60 minute room temperature resting step between the PEBs. The images in FIG. 4 qualitatively show the effect on pattern fidelity for undersized lines. The image from the wafer receiving no pause between PEBs shows significant amounts of line delamination and line collapse, whereas the image from the wafer received a 1 hour pause shows much few defects near the same CD. For the wafer that received no rest between PEBs, many defects such as line wiggling and line collapse is observed, whereas fewer such defects are observed for the wafer that received a rest step of 60 minutes between PEBs. This result is consistent with the theory of allowing water and/or other O-containing species to diffuse to the bottom of the resist film during the rest phase so that more complete hydrolysis/condensation can occur at the bottom of the film during the second PEB, and thereby improving the resist profile. Additional results are plotted in FIG. 5 that shows how the lower defect cliff (“cliff lower”), i.e., the minimum CD obtainable without having more than 10 defects/image, can be pushed to smaller CDs for processing using multiple PEB steps with rest periods between each PEB. Similarly, the DtS required to resolve such CDs is decreased. In particular, the wafers which received no rest between PEBs showed a lower defect cliff of approximately 9.80 nm and a DtS from about 36.15 to about 36.7 mJ/cm2. The lower defect cliff and the DtS were notably lower after a 30 second rest, approximately 9.60 nm-9.30 nm and 34.0-34.4 mJ/cm², respectively. The lower defect cliff and the DtS further decreased after a 60 minute rest to approximately 9.10 nm-9.15 nm and about 32.6 mJ/cm², respectively. The DtS for the two wafers processed with a 60 minute rest between PEBs was more similar than for the other wafer pairs.

The above example and data shown in FIGS. 4 and 5 show that for wafers that are rested between the two PEB processes, widening of the process window for smaller CDs with lower defects and lower dose-to-size values can be obtained. The results suggest that the rest between the two PEB processes can also improve patterning uniformity.

### Example 2: Processing with Vacuum Treatment

This example demonstrates the effectiveness of a vacuum treatment between PEB steps at lowering the patterning dose for an organotin photoresist.

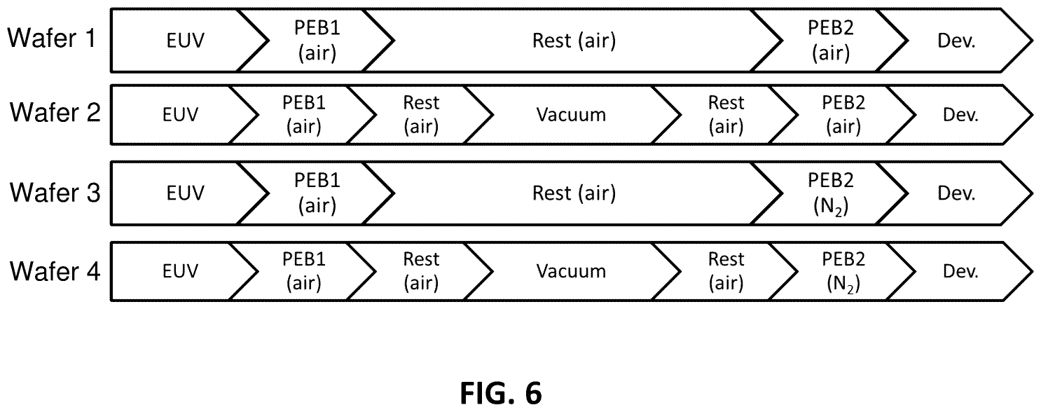

A series of photoresist films were prepared by spin coating a commercial organotin photoresist (Inpria YATU1011 resist) onto Si wafers that were previously coated with approximately 10 nm spin-on-glass (SOG). The organotin photoresist film thicknesses were measured to be about 22 nm by ellipsometry. The films were subjected to a PAB at 100° C. for 60 s. The films were then patterned with EUV radiation using an ASML NXE3400B EUV exposure tool to create an array of line/space patterns having a target line CD of 14 nm on a 28 nm pitch (14p28). The nominal 14p28 patterns were imaged at various doses across each wafer in a dose-meander type of layout wherein the fields on each wafer were imaged with the same photomask pattern at different doses. Following exposure, each wafer was subjected to a first PEB (PEB1) in air at 180° C. for 60 s. Next, two of the wafers were subjected to a vacuum treatment prior to being subjected to a second PEB (PEB2) at 200° C. for 60 s in either air or nitrogen (N₂) as indicated in Table 1 and illustrated in FIG. 6.

TABLE 1

| | | Vacuum | |
|---|---|---|---|
| Wafer # | PEB1 | Treatment | PEB2 |
| 1 | air | none | air |
| 2 | air | 60 seconds | air |
| 3 | air | none | N₂ |
| 4 | air | 60 seconds | N₂ |

The vacuum treatment was conducted on a TEL Certas LEAGA™ tool at a pressure of 0.26 mbar for 60 s followed by storage in a wafer FOUP (“Front Opening Unified Pod”) for 48 hours. The FOUP are sealed with clean facility air for storage. For wafers receiving no vacuum treatment, the wafers were stored in a wafer FOUP for 48 hours prior to PEB2.

After completion of the rest step, the wafers were developed using a thermal gas development process (“Dev” in FIG. 6) using a TEL Lithius ProZ wafer track via exposure to a flowing reactive gas of acetic acid at a temperature of 180° C. for 120 s to remove the unexposed photoresist material. See, for example, published U.S. patent application 2023/0100995 to Cardineau et al., entitled “High Resolution Latent Image Processing, Contrast Enhancement and Thermal Development,” incorporated herein by reference. Finally, the wafers were subjected to a hard bake at 250° C. for 60 s.

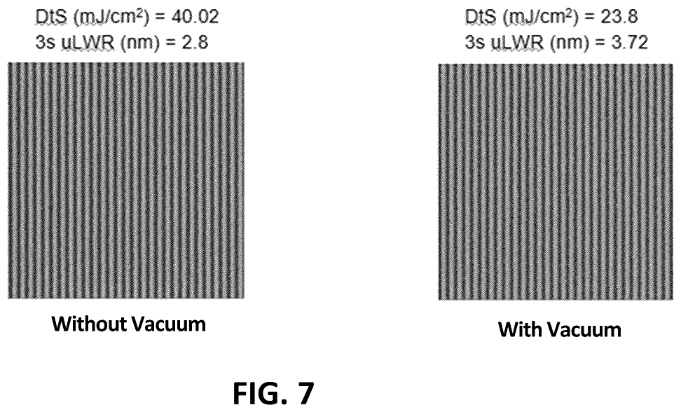

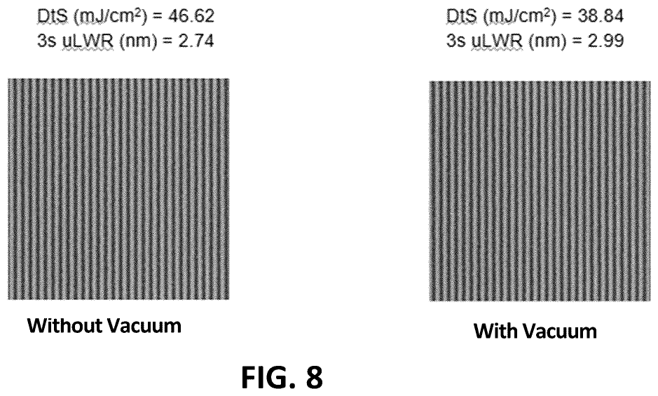

Each wafer was analyzed using a Hitachi CDSEM and images were captured at each exposed field to determine the dose corresponding to the nominal 14p28 line/space patterns on each wafer. FIG. 7 shows SEM images for wafer 1 (left image) and wafer 2 (right image), processed without and with a vacuum treatment, respectively. FIG. 8 shows SEM images for wafer 3 (left image) and wafer 4 (right image), processed with a second PEB bake in nitrogen and without and with a vacuum treatment, respectively. The results are summarized in Table 2.

TABLE 2

| | Dose-to-Size | LWR |
|---|---|---|
| Wafer # | (mJ/cm²) | (nm) |
| 1 | 40.02 | 2.80 |
| 2 | 23.80 | 3.72 |
| 3 | 46.62 | 2.74 |
| 4 | 38.84 | 2.99 |

As shown in Table 2, the wafers subjected to a vacuum treatment between the two PEBs showed significantly lower dose-to-size values for the 14p28 line/space patterns. For wafer 2 having both PEB1 and PEB2 conducted in air and having an intermediate vacuum treatment, the dose-to-size was nearly half of the dose-to-size for wafer 1 that was not subjected to an intermediate vacuum treatment. The LWR of wafer 2 was moderately higher than the LWR for wafer 1 which may be due to the lower patterning doses generally having a higher stochastic effect from the significantly lower photon counts required to achieve the lower does. A more modest reduction in dose-to-size (about 17%) was observed for wafer 4 which was subjected to a vacuum treatment prior to being subjected to a second PEB in a nitrogen atmosphere compared to wafer 3 which did not receive an intermediate vacuum treatment. For the wafers processed with a second PEB in an inert environment (e.g., N₂), the LWR for the vacuum-treated wafer 4 was slightly higher than for wafer 3. In particular, the line width roughness showed an approximate 9% increase, which is lower than the 33% increase measured for the wafers processed with a second PEB in air compared with a PEB in nitrogen.

The magnitude of the dose reduction seen for the vacuum treatment was not as large for PEB2 conducted in an inert atmosphere (about 17% lower) as compared to when the second PEB was conducted in air (about 41% lower). The difference in dose-to-size seen between processing with a second PEB performed in air versus nitrogen may indicate that significant chemical changes are occurring during the vacuum treatment. Additional FTIR results (not presented) show decreases in C—H signals and increases in OH signals during the second PEB for wafers subjected to a vacuum rest period, which suggests that the vacuum treatment improves Sn—C cleavage (organic removal) during the second PEB. It is further observed that an intermediate vacuum treatment renders the material less susceptible to removal during development. While not wanting to be limited by theory, chemical changes may occur during the vacuum treatment that make the exposed material more reactive during the second PEB. For example, the vacuum treatment may promote the dehydration and condensing of the exposed regions or enhance removal of organic material from the exposed material, or the exposed material may be more susceptible to hydrolysis/condensation during a PEB in air following the vacuum treatment. In any case, the results show that the intermediate vacuum treatment can enable lower patterning doses for organotin photoresist and that line width roughness may be modulated by adjusting the atmosphere of the second PEB.

The results described in this Example show that a vacuum treatment between two PEB steps can be effective at lowering the patterning dose required for organotin photoresists and suggests that vacuum treatment can be used more generally during lithographic processing of organometallic photoresists to further improve patterning efficiency and performance.

### Further Inventive Concepts

A1. A method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature from about 45° C. to about 220° C. for about 0.1 minutes to about 30 minutes;
after removing the irradiated structure from the first temperature, resting the irradiated structure for about 1 minute to about 5000 minutes at a pressure of at least about 600 Torr to form a first rested structure;
resting the first rested structure at a pressure of no more than about 150 Torr for 0.1 minutes to about 30 minutes to form a second rested structure;
resting the second rested structure for about 1 minute to about 5000 minutes at a pressure of at least about 600 Torr to form a third rested structure;
heating the third rested structure at a second temperature from about 45° C. to about 250° C. for about 0.1 minutes to about 30 minutes; and
developing the coated substrate after the second heating step to form a physically patterned structure.

A2. The method of inventive concept A1 wherein the second temperature is greater than the first temperature.

A3. The method of inventive concept A1 wherein the radiation comprises EUV radiation.

A4. The method of inventive concept A1 wherein heating the irradiated structure is performed in air.

A5. The method of inventive concept A4 wherein the air has a room temperature-relative humidity of at least about 65%.

A6. The method of inventive concept A1 wherein the first temperature is from about 60° C. to about 220° C.

A7. The method of inventive concept Al wherein while resting at a pressure of at least about 600 Torr, subjecting the irradiated structure to an elevated relative humidity atmosphere.

A8. The method of inventive concept A7 wherein the elevated relative humidity atmosphere has a room temperature relative humidity of at least about 65%.

A9. The method of inventive concept A7 wherein the irradiated structure is subjected to the elevated relative humidity atmosphere for from about 10 seconds to about 60 minutes.

A10. The method of inventive concept A1 wherein resting at a pressure of at least about 600 Torr is performed for about 2 minutes to about 90 minutes.

A11. The method of inventive concept 1 wherein resting at a pressure of no more than about 150 Torr is performed for about 0.2 minutes to about 10 minutes.

A12. The method of inventive concept A1 wherein resting at a pressure of at least about 600 Torr is performed in an atmosphere having a controlled concentration of H₂O, O₂, NOₓ, and/or an inert composition.

A13. The method of inventive concept A1 wherein resting at a pressure of at least about 600 Torr is performed in ambient air.

A14. The method of inventive concept A1 wherein resting the first rested structure is performed at a pressure of no more than about 1 Torr.

A15. The method of inventive concept A1 wherein resting the first rested structure is performed in an atmosphere that is essentially free of humidity.

A16. The method of inventive concept A1 wherein heating the third rested structure is performed in air.

A17. The method of inventive concept A1 wherein heating the third rested structure is performed in an inert gas atmosphere.

A18. The method of inventive concept A17 wherein the inert gas atmosphere comprises nitrogen, a noble gas, or a mixture thereof.

A19. The method of inventive concept A1 wherein the second temperature from about 80° C. to about 220° C.

A20. The method of inventive concept A1 wherein one or more of the steps after irradiating and before developing are performed in an atmosphere comprising a mixture of an inert gas and a controlled amount of water.

A21. The method of inventive concept A20 wherein the atmosphere comprises a relative humidity of at least about 65%.

A22. The method of inventive concept A1 wherein the heating and resting steps are repeated one or more times prior to developing.

A23. The method of inventive concept A1 wherein developing comprises dry development.

A24. The method of inventive concept A23 wherein dry development is performed with carboxylic acid vapor.

A25. The method of inventive concept A24 wherein the carboxylic acid comprises acetic acid.

A26. The method of inventive concept A1 wherein developing is performed with organic solvent or an aqueous acid or base.

A27. The method of inventive concept A1 further comprising resting the irradiated structure for about 1 minute to about 300 minutes prior to heating the irradiated structure.

A28. The method of inventive concept A27 further comprising heating the coated substrate at a temperature from about 25° C. to about 250° C. for about 0.1 minutes to about 30 minutes prior to irradiating to form a heated coated substrate.

A29. The method of inventive concept A28 further comprising resting the heated coated substrate for from about 1 minute to about 30 minutes prior to irradiating.

A30. The method of inventive concept A1 further comprising heating the physically patterned structure at a temperature from about 100° C. to about 600° C. for about 0.1 minutes to about 30 minutes.

A31. The method of inventive concept A30 further comprising resting the physically patterned structure for from about 1 minute to about 30 minutes prior to heating the physically patterned structure.

A32. The method of inventive concept A1 wherein the film comprises a tin oxo-hydroxo network.

A33. The method of inventive concept A1 wherein the film has an average thickness from about 1 nm to about 50 nm.

B1. A method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature from about 45° C. to about 220° C. for about 0.1 minutes to about 30 minutes to form a first heated structure;
resting the first heated structure at a relative humidity of at least about 65% for 0.1 minute to about 5000 minutes to form a rested structure;
heating the rested structure at a second temperature from about 45° C. to about 250° C. for about 0.1 minutes to about 30 minutes; and
developing the coated substrate after the second heating step to form a physically patterned structure.

B2. The method of inventive concept B1 wherein the second temperature is greater than the first temperature.

B3. The method of inventive concept B1 wherein the radiation comprises EUV radiation.

B4. The method of inventive concept B1 wherein heating the irradiated structure is performed in air.

B5. The method of inventive concept B4 wherein the air has a room temperature-relative humidity of at least about 65%.

B6. The method of inventive concept B1 wherein the first temperature is from about 60° C. to about 220° C.

B7. The method of inventive concept B1 wherein resting is performed at a pressure of at least about 600 Torr.

B8. The method of inventive concept B1 wherein resting is performed at a relative humidity of at least about 70%.

B9. The method of inventive concept B1 wherein resting is performed for about 2 minutes to about 60 minutes.

B10. The method of inventive concept B1 wherein resting is performed in an atmosphere having a controlled concentration of H₂O, O₂, NOₓ, and/or an inert composition.

B11. The method of inventive concept B1 wherein heating the rested structure is performed in air.

B12. The method of inventive concept B1 wherein heating the rested structure is performed in an inert gas atmosphere.

B13. The method of inventive concept B12 wherein the inert gas atmosphere comprises nitrogen, a noble gas, or a mixture thereof.

B14. The method of inventive concept B12 wherein the inert gas atmosphere is essentially free of humidity.

B15. The method of inventive concept B1 wherein the second temperature from about 80° C. to about 220° C.

B16. The method of inventive concept B1 wherein heating the irradiated structure and heating the rested structure are performed in an atmosphere comprising a mixture of an inert gas and a controlled amount of water.

B17. The method of inventive concept B16 wherein the atmosphere comprises a relative humidity of at least about 65%.

B18. The method of inventive concept B1 wherein heating the irradiated structure, resting, and heating the rested structure are repeated one or more times prior to developing.

B19. The method of inventive concept B1 wherein heating the irradiated structure is performed in air and wherein heating the rested structure is performed in air or in an inert atmosphere.

B20. The method of inventive concept B1 wherein developing comprises dry development.

B21. The method of inventive concept B20 wherein dry development is performed with carboxylic acid vapor.

B22. The method of inventive concept B21 wherein the carboxylic acid comprises acetic acid.

B23. The method of inventive concept B1 wherein developing is performed with organic solvent or an aqueous acid or base.

B24. The method of inventive concept B1 further comprising resting the irradiated structure for about 1 minute to about 300 minutes prior to heating the irradiated structure.

B25. The method of inventive concept B24 further comprising heating the coated substrate at a temperature from about 25° C. to about 250° C. for about 0.1 minutes to about 30 minutes prior to irradiating to form a heated coated substrate.

B26. The method of inventive concept B25 further comprising resting the heated coated substrate for about 1 minute to about 30 minutes prior to irradiating.

B27. The method of inventive concept B1 further comprising heating the physically patterned structure at a temperature from about 100° C. to about 600° C. for about 0.1 minutes to about 30 minutes.

B28. The method of inventive concept B27 further comprising resting the physically patterned structure for from about 1 minute to about 30 minutes prior to heating the physically patterned structure.

B29. The method of inventive concept B1 wherein the film comprises a tin oxo-hydroxo network.

B30. The method of inventive concept B1 wherein the film has an average thickness from about 1 nm to about 50 nm.

C1. A method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature under an elevated relative humidity corresponding to a room temperature relative humidity of at least about 61% from about 45° C. to about 220° C. for about 0.1 minutes to about 30 minutes;
resting the irradiated structure for about 1 minute to about 5000 minutes to form a rested structure;
heating the rested structure at a second temperature from about 45° C. to about 250° C. for about 0.1 minutes to about 30 minutes; and
developing the coated substrate after the second heating step to form a physically patterned structure.

C2. The method of inventive concept C1 wherein heating the irradiated structure is performed in air and wherein the heating of the rested structure is performed in air or in an inert atmosphere.

C3. The method of inventive concept C1 wherein the second temperature is greater than the first temperature.

C4. The method of inventive concept C1 wherein the radiation comprises EUV radiation.

C5. The method of inventive concept C1 wherein the elevated relative humidity corresponds to a room temperature relative humidity of at least about 65%.

C6. The method of inventive concept C1 wherein the elevated relative humidity corresponds to a room temperature relative humidity of at least about 90%.

C7. The method of inventive concept C1 wherein the first temperature is from about 60° C. to about 220° C.

C8. The method of inventive concept C1 wherein resting is performed at a pressure of at least about 600 Torr.

C9. The method of inventive concept C2 wherein resting is performed at least in part in an atmosphere having a controlled concentration of H₂O, O₂, NOₓ, and/or an inert composition.

C10. The method of inventive concept C1 wherein resting is performed at a relative humidity of at least about 65%.

C11. The method of inventive concept C1 wherein resting is performed in ambient air having a room temperature-relative humidity of at least about 65%.

C12. The method of inventive concept C1 wherein resting is performed for about 2 minutes to about 60 minutes.

C13. The method of inventive concept C1 wherein resting is performed in one or more stages each covering a selected fraction of the rest time, wherein the one or more stages comprise a reduced pressure environment stage having a pressure below about 150 Torr.

C14. The method of inventive concept C13 wherein the reduced pressure environment stage is performed for at least about 0.2 minutes.

C15. The method of inventive concept C13 wherein the pressure is no more than about 150 Torr.

C16. The method of inventive concept C13 wherein the one or more stages further comprise an ambient environment stage.

C17. The method of inventive concept C1 wherein heating the rested structure is performed in air

C18. The method of inventive concept C1 wherein heating the rested structure is performed in an inert gas atmosphere.

C19. The method of inventive concept C18 wherein the inert gas atmosphere comprises nitrogen, a noble gas, or a mixture thereof.

C20. The method of inventive concept C1 wherein the second temperature from about 80° C. to about 200° C.

C21. The method of inventive concept C1 wherein heating the irradiated structure, resting, and heating the rested structure are repeated one or more times prior to developing.

C22. The method of inventive concept C1 wherein developing comprises dry development.

C23. The method of inventive concept C22 wherein dry development is performed with carboxylic acid vapor.

C24. The method of inventive concept C23 wherein the carboxylic acid comprises acetic acid.

C25. The method of inventive concept C1 wherein developing is performed with organic solvent or an aqueous acid or base.

C26. The method of inventive concept C1 further comprising resting the irradiated structure for about 1 minute to about 300 minutes prior to heating the irradiated structure.

C27. The method of inventive concept C26 further comprising heating the coated substrate at a temperature from about 25° C. to about 220° C. for about 0.1 minutes to about 30 minutes prior to irradiating to form a heated coated substrate.

C28. The method of inventive concept C27 further comprising resting the heated coated substrate for about 1 minute to about 30 minutes prior to irradiating.

C29. The method of inventive concept C1 further comprising heating the physically patterned structure at a temperature from about 100° C. to about 600° C. for about 0.1 minutes to about 30 minutes.

C30. The method of inventive concept C29 further comprising resting the physically patterned structure for from about 1 minute to about 30 minutes prior to heating the physically patterned structure.

C31. The method of inventive concept C1 wherein the film comprises a tin oxo-hydroxo network.

C32. The method of inventive concept C1 wherein the film has an average thickness from about 1 nm to about 50 nm.

D1. A method for patterning a coated substrate with radiation wherein the coated substrate has a substrate with a film on a surface of the substrate and wherein the film comprises an organotin composition, the method comprising:
irradiating a coated substrate with radiation to form an irradiated structure;
resting the irradiated structure for a first rest period for about 1 minute to about 30 minutes to form a first rested structure;
heating the rested structure at a first temperature from about 45° C. to about 220° C. under an elevated relative humidity corresponding to a room temperature relative humidity of at least about 61% for about 0.1 minutes to about 30 minutes;
after removing the irradiated structure from the first temperature, resting the irradiated structure for a second rest period from about 0.1 minutes to about 5000 minutes to form a further rested structure wherein at least a portion of the second rest period comprises contacting the irradiated coated substrate with an inert atmosphere, a pressure of no more than about 150 Torr, or a relative humidity of at least about 65%; and
developing the stored structure to form a physically patterned structure.

D2. The method of inventive concept D1 wherein prior to developing, heating the further rested structure at a second temperature from about 80° C. to about 250° C. for about 0.1 minutes to about 30 minutes.

D3. The method of inventive concept D1 wherein the radiation comprises EUV radiation.

D4. The method of inventive concept D1 wherein at least a portion of the first rest period comprises contacting the irradiated coated substrate with ambient air, an inert atmosphere, a controlled pressure, or a relative humidity of at least about 65%.

D5. The method of inventive concept D1 wherein resting the irradiated structure for a first rest period is performed in ambient air.

D6. The method of inventive concept D1 wherein resting the irradiated structure for a first rest period is performed in air having a relative humidity of at least about 65%.

D7. The method of inventive concept D4 wherein the controlled pressure is a pressure of at least about 600 Torr.

D8. The method of inventive concept D4 wherein the controlled pressure is a pressure of no more than about 150 Torr.

D9. The method of inventive concept D1 wherein heating the rested structure is performed in air.

D10. The method of inventive concept D1 wherein heating the rested structure is performed in air or in an inert gas atmosphere.

D11. The method of inventive concept D10 wherein the inert gas atmosphere comprises nitrogen, a noble gas, or a mixture thereof.

D12. The method of inventive concept D1 wherein the elevated relative humidity corresponds to a room temperature relative humidity of at least about 65%.

D13. The method of inventive concept D1 wherein the first temperature from about 60° C. to about 220° C.

D14. The method of inventive concept D1 wherein resting the irradiated structure for a second rest period is performed in ambient air.

D15. The method of inventive concept D1 wherein resting the irradiated structure for a second rest period is performed in air having a relative humidity of at least about 65%.

D16. The method of inventive concept D1 wherein resting the irradiated structure for a second rest period is performed at a pressure of no more than about 150 Torr.

D17. The method of inventive concept D1 wherein resting the irradiated structure for a second rest period is performed for about 2 minutes to about 90 minutes.

D18. The method of inventive concept D1 wherein resting the irradiated structure for a second rest period comprises contacting the irradiated coated substrate with, sequentially, a relative humidity of at least about 65%, a pressure of no more than about 150 Torr, and an air atmosphere.

D19. The method of inventive concept D1 wherein resting the irradiated structure for a second rest period comprises contacting the irradiated coated substrate with a pressure of no more than about 150 Torr for about 0.2 minutes to about 10 minutes.

D20. The method of inventive concept D19 wherein the pressure is no more than about 1 Torr.

D21. The method of inventive concept D1 wherein developing comprises dry development.

D22. The method of inventive concept D21 wherein dry development is performed with carboxylic acid vapor.

D23. The method of inventive concept D22 wherein the carboxylic acid comprises acetic acid.

D24. The method of inventive concept D1 wherein developing is performed with organic solvent or an aqueous acid or base.

D25. The method of inventive concept D1 further comprising heating the coated substrate at a temperature from about 25° C. to about 250° C. for about 0.1 minutes to about 30 minutes prior to irradiating to form a heated coated substrate.

D26. The method of inventive concept D25 further comprising resting the heated coated substrate for about 1 minute to about 30 minutes prior to irradiating.

D27. The method of inventive concept D1 further comprising heating the physically patterned structure at a temperature from about 100° C. to about 600° C. for about 0.1 minutes to about 30 minutes.

D28. The method of inventive concept D27 further comprising resting the physically patterned structure for from about 1 minute to about 30 minutes prior to heating the physically patterned structure.

D29. The method of inventive concept D1 wherein the film comprises a tin oxo-hydroxo network.

D30. The method of inventive concept D1 wherein the film has an average thickness from about 1 nm to about 50 nm.

D31. The method of inventive concept D1 further comprising heating the further rested structure prior to development at a second temperature from about 45° C. to about 250° C. for about 0.1 minutes to about 30 minutes.

D32. The method of inventive concept D31 wherein the heating the further rested structure is performed in air.

D33. The method of inventive concept D31 wherein the heating the further rested structure is performed in inert gas.

The embodiments above are intended to be illustrative and not limiting. Additional embodiments are within the claims and additional inventive concepts. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated.

What is claimed is:

1. A method for patterning a coated substrate with radiation wherein the coated substrate has a substrate with a film on a surface of the substrate and wherein the film comprises an organotin composition, the method comprising:
irradiating a coated substrate with radiation to form an irradiated structure;
heating the irradiated structure at a first temperature from about 45° C. to about 220° C. for about 0.1 minutes to about 30 minutes;
after removing the irradiated structure from the first temperature, resting the irradiated structure for about 1 minute to about 5000 minutes to form a rested structure;
heating the rested structure at a second temperature from about 45° C. to about 250° C. for about 0.1 minutes to about 30 minutes; and
developing the coated substrate after the second heating step to form a physically patterned structure.

2. The method of claim 1 wherein the radiation comprises EUV radiation.

3. The method of claim 1 wherein heating the irradiated structure is performed in air.

4. The method of claim 3 wherein the air has a room temperature-relative humidity of at least about 65%.

5. The method of claim 1 wherein the first temperature is from about 60° C. to about 200° C.

6. The method of claim 1 wherein while resting, subjecting the irradiated structure to an elevated relative humidity atmosphere.

7. The method of claim 6 wherein the elevated relative humidity atmosphere has a room temperature relative humidity of at least about 65%.

8. The method of claim 6 wherein the irradiated structure is subjected to the elevated relative humidity atmosphere for about 10 seconds to about 60 minutes.

9. The method of claim 1 wherein resting is performed for about 2 minutes to about 90 minutes.

10. The method of claim 1 wherein resting is performed at least in part in an atmosphere having a controlled concentration of H₂O, O₂, NOₓ, and/or an inert composition.

11. The method of claim 1 wherein resting is performed in ambient air.

12. The method of claim 1 wherein resting is performed in one or more stages, wherein the one or more stages comprise a reduced pressure environment stage having a pressure below about 150 Torr.

13. The method of claim 12 wherein the reduced pressure environment stage is performed for at least about 0.2 minutes.

14. The method of claim 12 wherein the pressure is no more than about 25 Torr.

15. The method of claim 12 wherein the pressure is no more than about 1 Torr.

16. The method of claim 12 wherein the one or more stages further comprise an ambient environment stage.

17. The method of claim 1 wherein resting comprises sequentially a first ambient air stage, a reduced pressure environment stage having a pressure below about 150 Torr, and a second ambient air stage.

18. The method of claim 17 wherein the first ambient air stage, the reduced pressure environment stage, and the second ambient air stage are independently from about 1 minute to about 30 minutes.

19. The method of claim 1 wherein heating the rested structure is performed in air.

20. The method of claim 1 wherein heating the rested structure is performed in an inert gas atmosphere.

21. The method of claim 20 wherein the inert gas atmosphere comprises nitrogen, a noble gas, or a mixture thereof.

22. The method of claim 20 wherein the inert gas atmosphere is essentially free of humidity.

23. The method of claim 1 wherein the second temperature is from about 80° C. to about 220° C.

24. The method of claim1 wherein the second temperature is greater than the first temperature.

25. The method of claim 1 wherein the first heating step, the resting step, and/or the second heating step are performed in an atmosphere comprising a mixture of an inert gas and a controlled amount of water.

26. The method of claim 25 wherein the atmosphere comprises a relative humidity of at least about 65%.

27. The method of claim 1 wherein the first heating step, the resting step, and the second heating step are repeated one or more times prior to developing.

28. The method of claim 1 wherein developing comprises dry development.

29. The method of claim 28 wherein dry development is performed with carboxylic acid vapor.

30. The method of claim 29 wherein the carboxylic acid comprises acetic acid.

31. The method of claim 1 wherein developing is performed with organic solvent or an aqueous acid or base.

32. The method of claim 1 further comprising resting the irradiated structure for about 1 minute to about 300 minutes prior to heating the irradiated structure.

33. The method of claim 32 further comprising heating the coated substrate at a temperature from about 25° C. to about 250° C. for about 0.1 minutes to about 30 minutes prior to irradiating to form a heated coated substrate.

34. The method of claim 33 further comprising resting the heated coated substrate for about 1 minute to about 30 minutes prior to irradiating.

35. The method of claim 1 further comprising heating the physically patterned structure at a temperature from about 100° C. to about 600° C. for about 0.1 minutes to about 30 minutes.

36. The method of claim 35 further comprising resting the physically patterned structure for about 1 minute to about 30 minutes prior to heating the physically patterned structure.

37. The method of claim 1 wherein the film comprises a tin oxo-hydroxo network.

38. The method of claim 1 wherein the film has an average thickness from about 1 nm to about 50 nm.
